(19) United States
(12) Patent Application Publication
(10) Pub. No.: US 2007/0272545 A1
(43) Pub. Date: Nov. 29, 2007

(54) APPARATUS FOR PROCESSING SUBSTRATE AND METHOD OF PROCESSING SUBSTRATE

(76) Inventor: Masahiro Miyagi, Kyoto (JP)

Correspondence Address: OSTROLENK FABER GERB & SOFFEN, 1180 AVENUE OF THE AMERICAS, NEW YORK, NY, 100368403, US

(21) Appl. No.: 11/745,652

(22) Filed: May 8, 2007

(30) Foreign Application Priority Data
May 24, 2006 (JP) P2006-144431

(51) Int. Cl. C25D 17/00; H01L 21/44

(52) U.S. Cl. 204/198; 438/612; 204/227

(57) ABSTRACT

A substrate processing apparatus comprises an applying part for applying droplets of cleaning solution onto a substrate, a ring-shaped induction electrode located close to an outlet of the applying part, and an applying part moving mechanism for moving the applying part. In the substrate processing apparatus, electric potential difference is generated between the induction electrode and a cleaning solution tube in the applying part, positive charge is induced on the cleaning solution, and the substrate is cleaned by the droplets of the cleaning solution, whereby the substrate can be suppressed to be negatively charged during cleaning. Concurrently with movement of the applying part and application of the cleaning solution, the electric potential difference is controlled on the basis of the characteristics of charging of the substrate and relative position of the applying part to the substrate. It is possible to improve uniformity of distribution of electric potentials on the substrate.

### BACKGROUND OF THE INVENTION

1. Field of the Invention

The present invention relates to a technique for processing a substrate by applying processing liquid onto the substrate.

2. Description of the Background Art

Conventionally, in manufacturing process of a semiconductor substrate (hereinafter, simply referred to as “substrate”), various processings are performed by supplying processing liquid onto a substrate. For example, unwanted particles and the like adhering on the surface of the substrate are removed by applying cleaning solution such as pure water onto the substrate in a cleaning process of substrate.

Meanwhile, in such a cleaning process, it has been known that the whole surface of the substrate on which an insulating film is formed is charged by contacting with pure water having a high specific resistance. For example, the substrate is negatively charged in a case where an oxide film is formed on a surface of a substrate and conversely the substrate is positively charged in a case where a resist film is formed on a surface of a substrate. When a surface charge of the substrate is large, there is a possibility of occurrence of re-adhesion of unwanted particles or damage on wiring caused by electric discharge during and after cleaning or the like. Therefore, various techniques for suppressing charging of a substrate in a substrate processing apparatus have been suggested.

For example, Japanese Patent Application Laid-Open No. 2002-184660 (Document 1) discloses a technique for suppressing charging of a surface of a substrate in an apparatus where ionized nitrogen gas is purged into a processing space above the substrate, and the substrate is cleaned by applying cleaning solution onto the substrate which is rotated. Japanese Patent Application Laid-Open No. 2005-183791 (Document 2) discloses a technique for suppressing charging of surfaces of substrates in an apparatus where the substrates are dipped into cleaning solution stored in a process bath and a CO₂-dissolved water having a lower specific resistance than pure water which is generated by dissolving carbon gas into pure water is applied onto the substrates in exchanging of cleaning solution.

Japanese Patent Application Laid-Open No. 10-149893 (Document 3) discloses an apparatus for removing static electricity of charged substances, where pure water is ejected from a nozzle at high speed to generate fine droplets of the pure water which are charged by flow friction with the nozzle and the charged droplets are applied onto the charged substances. The apparatus can be applied to a charged semiconductor substrate after cleaning.

“Charged Fog Generated from Collision between Water Jet and Silicon Wafer” by Kazuaki ASANO and Hiroflmi SHIMOKAWA (IEJ (The Institute of Electrostatics Japan) transactions' 00 (March 2000), IEJ, March 2000, pp. 25-26) (Document 4) describes experiments on a generation process of charged fog which is generated when a jet of pure water ejected from a nozzle collides with a silicon wafer. In an apparatus used in the experiments, an induction electrode is arranged in a path of ejection of pure water and an amount of charging of jet is controlled to change an amount of charging of charged fog.

However, in the cleaning process performed in the ionized gas atmosphere as disclosed in Document 1, it is difficult to apply the ionized gas onto the surface of the substrate continuously and efficiently, and this causes a limitation of suppressing charging of the substrate. In the apparatuses shown in Documents 2 and 3, it is not possible to suppress charging of the substrate during cleaning process.

Even if a cleaning process is performed while suppressing charging of the whole surface of a substrate under the same conditions, there is a case where a degree of suppression of charging in the central portion of the substrate is greater than that in the periphery, depending on a kind of insulating film formed on the substrate. In this case, if it is tried to fully suppress charging in the periphery of the substrate, the central portion of the substrate may be charged to a reverse polarity.

On the other hand, when the cleaning process of a substrate is performed without suppression of charging, a uniform distribution of electric potentials on the substrate is not necessarily measured. For example, in a case where an oxide film is formed on the surface of the substrate, a surface charge in the central portion of the substrate is greater than that in the periphery. Contrary to the above case, if a degree of suppression of charge in the whole surface of the substrate is uniform, the periphery of the substrate may be charged to a reverse polarity in full suppression of charging in the central portion of the substrate.

### SUMMARY OF THE INVENTION

The present invention is intended for a substrate processing apparatus for processing a substrate by applying processing liquid onto the substrate. It is an object of the present invention to improve uniformity of a distribution of electric potentials on the substrate while suppressing charging of the substrate during processing.

The substrate processing apparatus comprises an applying part for applying processing liquid from an outlet onto a main surface of a substrate; a processing liquid supply part for supplying the processing liquid into the applying part; an induction electrode which is electrically insulated from the applying part and located close to the outlet of the applying part or located at a position of the outlet, the induction electrode inducing charge on the processing liquid in the vicinity of the outlet by generating an electric potential difference between the induction electrode and a liquid contact part which is conductive and contacts the processing liquid in the applying part or the processing liquid supply part; an applying part moving mechanism for moving the applying part in parallel with the main surface of the substrate relatively to the substrate; and an electric potential difference control part for changing an electric potential difference generated between the liquid contact part and the induction electrode, concurrently with relative movement of the applying part to the substrate and application of the processing liquid. According to the present invention, it is possible to improve uniformity of a distribution of electric potentials on the substrate while suppressing charging of the substrate during processing.

According to a preferred embodiment of the present invention, the substrate processing apparatus further comprises a surface electrometer for measuring a distribution of electric potentials on the main surface of the substrate concurrently with relative movement of the applying part to the substrate and application of the processing liquid, and the electric potential difference control part changes the electric potential difference between the liquid contact part and the induction electrode on the basis of an output from the surface electrometer.

According to another preferred embodiment of the present invention, the applying part ejects droplets of the processing liquid onto the substrate. More preferably, the droplets of the processing liquid are generated by mixing the processing liquid and carrier gas in the applying part or in the vicinity outside the outlet.

According to still another preferred embodiment of the present invention, a specific resistance of the processing liquid is equal to or greater than 1×10² Ωm, and pure water or a CO₂-dissolved water where CO₂ gas is dissolved into pure water is used as the processing liquid.

According to an aspect of the present invention, a substrate processing apparatus comprises an applying part for applying processing liquid from an outlet onto a main surface of a substrate; a processing liquid supply part for supplying the processing liquid into the applying part; an induction electrode which is electrically insulated from the applying part and located close to the outlet of the applying part or located at a position of the outlet, the induction electrode inducing charge on the processing liquid in the vicinity of the outlet by generating an electric potential difference between the induction electrode and a liquid contact part which is conductive and contacts the processing liquid in the applying part or the processing liquid supply part; an applying part moving mechanism for moving the applying part in parallel with the main surface of the substrate relatively to the substrate; and a speed control part for changing a relative movement speed of the applying part to the substrate by control of the applying part moving mechanism, in relative movement of the applying part to the substrate which is concurrently performed with application of the processing liquid from the applying part. This makes it possible to improve uniformity of a distribution of electric potentials on the substrate while suppressing charging of the substrate during processing.

According to another aspect of the present invention, the substrate processing apparatus further comprises a surface electrometer for measuring a distribution of electric potentials on the main surface of the substrate concurrently with relative movement of the applying part to the substrate and application of the processing liquid, and the speed control part changes the relative movement speed of the applying part on the basis of an output from the surface electrometer.

The present invention is also intended for a substrate processing method of processing a substrate by applying processing liquid onto the substrate.

These and other objects, features, aspects and advantages of the present invention will become more apparent from the following detailed description of the present invention when taken in conjunction with the accompanying drawings.

### BRIEF DESCRIPTION OF THE DRAWINGS

FIG. 1 is a view showing a construction of a substrate processing apparatus in accordance with a first preferred embodiment;

FIG. 2 is a longitudinal sectional view showing the vicinity of an applying part;

FIG. 3 is a flowchart showing an operation flow for cleaning a substrate;

FIG. 4 is a view showing a distribution of electric potentials in a case where charge is not induced;

FIG. 5 is a view showing a distribution of electric potentials on the substrate in a case where cleaning is performed by cleaning solution with a constant charge;

FIG. 6A is a graph showing a relationship between a relative position of the applying part to the substrate and an electric potential difference between an induction electrode and a cleaning solution tube;

FIG. 6B is a graph showing another exemplary relationship between a relative position of the applying part to the substrate and an electric potential difference between an induction electrode and a cleaning solution tube;

FIG. 7 is a view showing a construction of a substrate processing apparatus in accordance with a second preferred embodiment;

FIG. 8 is a view showing a construction of a substrate processing apparatus in accordance with a third preferred embodiment;

FIG. 9 is a flowchart showing a part of operation flow for cleaning the substrate;

FIG. 10 is a view showing a construction of a substrate processing apparatus in accordance with a fourth preferred embodiment;

FIG. 11 is a view showing a construction of a substrate processing apparatus in accordance with a fifth preferred embodiment; and

FIG. 12 is a longitudinal sectional view showing another exemplary induction electrode.

### DESCRIPTION OF THE PREFERRED EMBODIMENTS

FIG. 1 is a view showing a construction of a substrate processing apparatus 1 in accordance with the first preferred embodiment of the present invention. The substrate processing apparatus 1 is an apparatus where a cleaning process is performed by applying cleaning solution onto a semiconductor substrate 9 (hereinafter, simply referred to as “substrate 9”) on which an insulating film is formed and foreign substances such as unwanted particles adhering on the surface of the substrate 9 are removed. As the cleaning solution, pure water having a specific resistance of about 1.8×10⁵ Ωm is used in the preferred embodiment. Cleaning is performed on the substrate 9 where an oxide film is formed on the surface in the preferred embodiment.

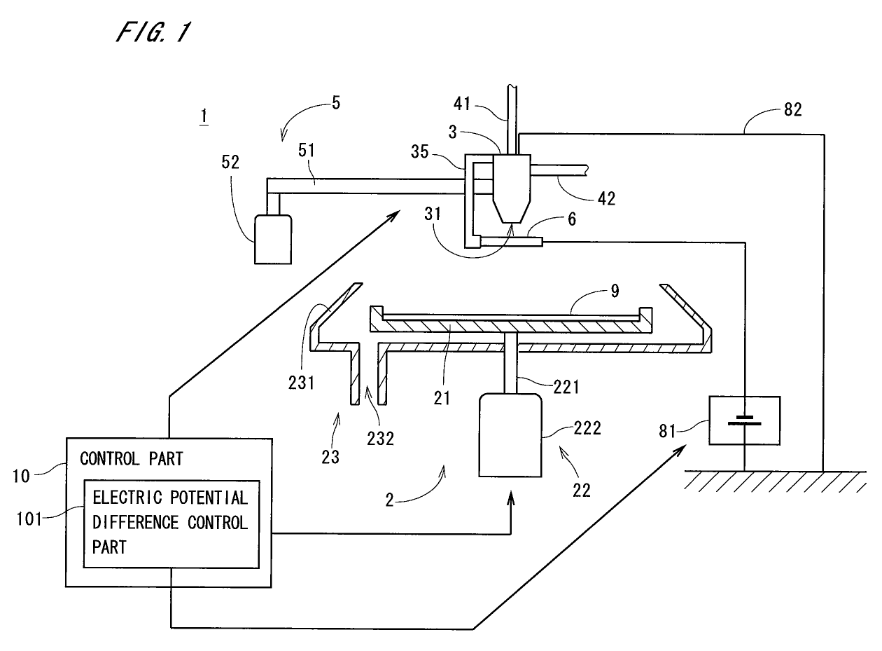

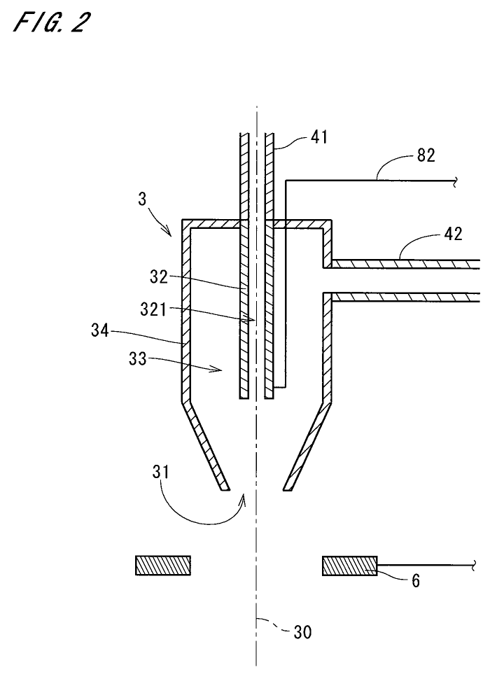

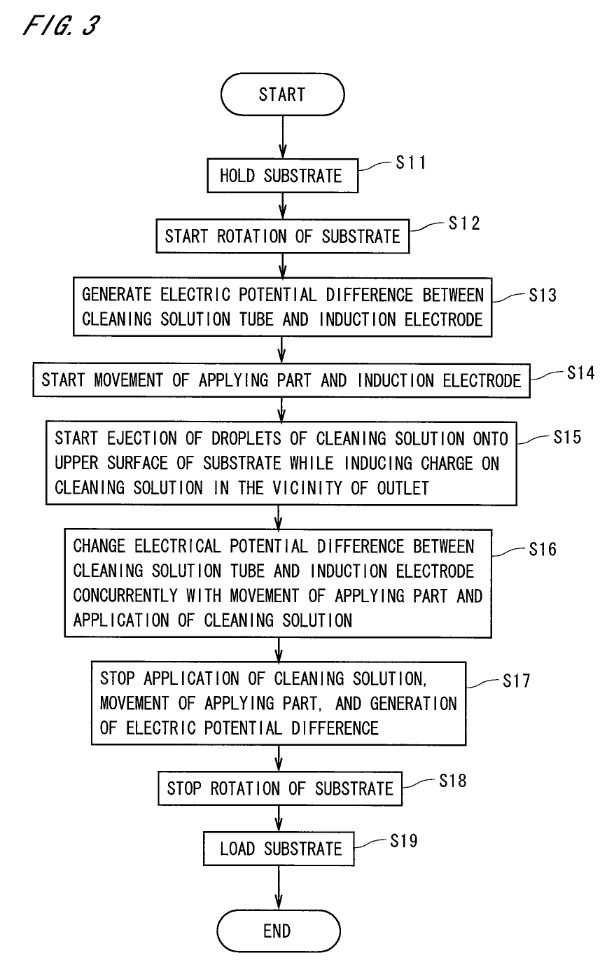

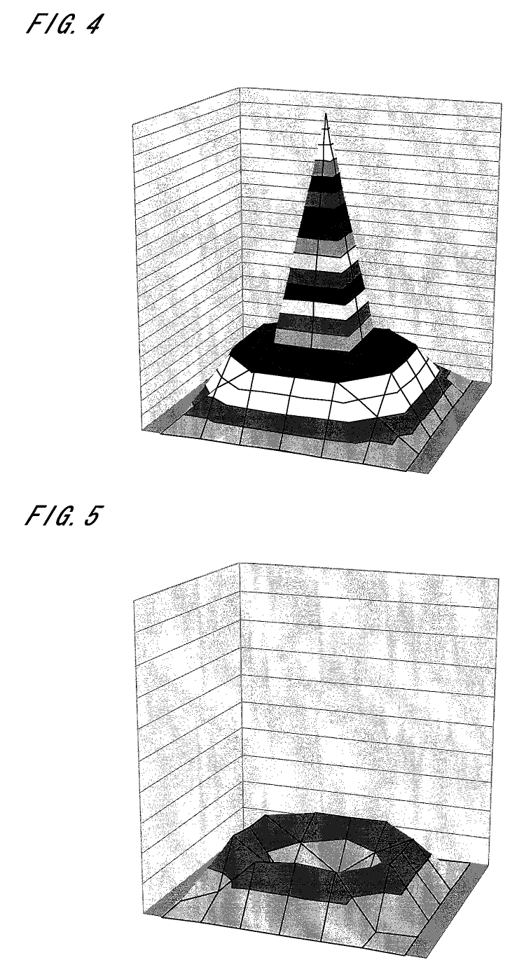

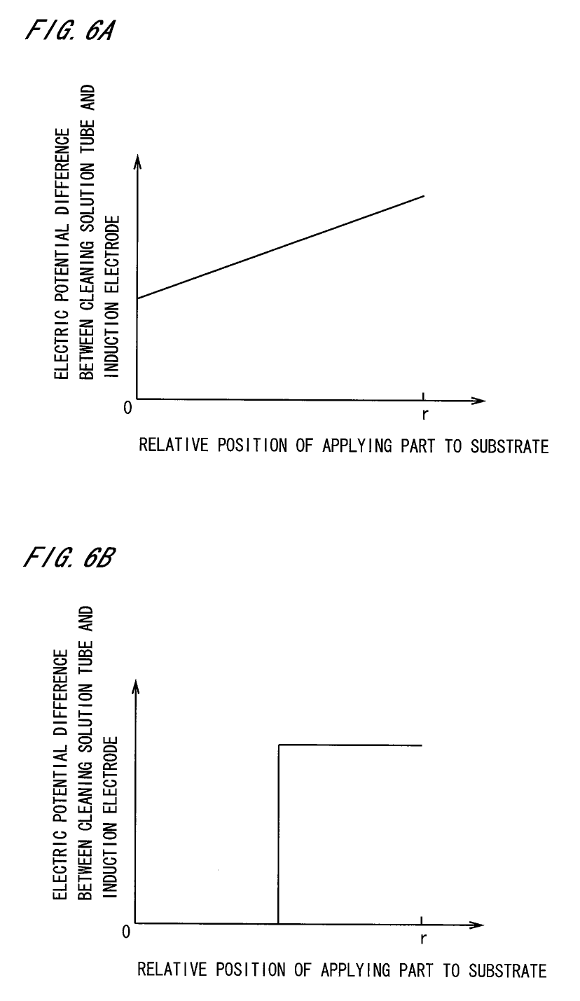

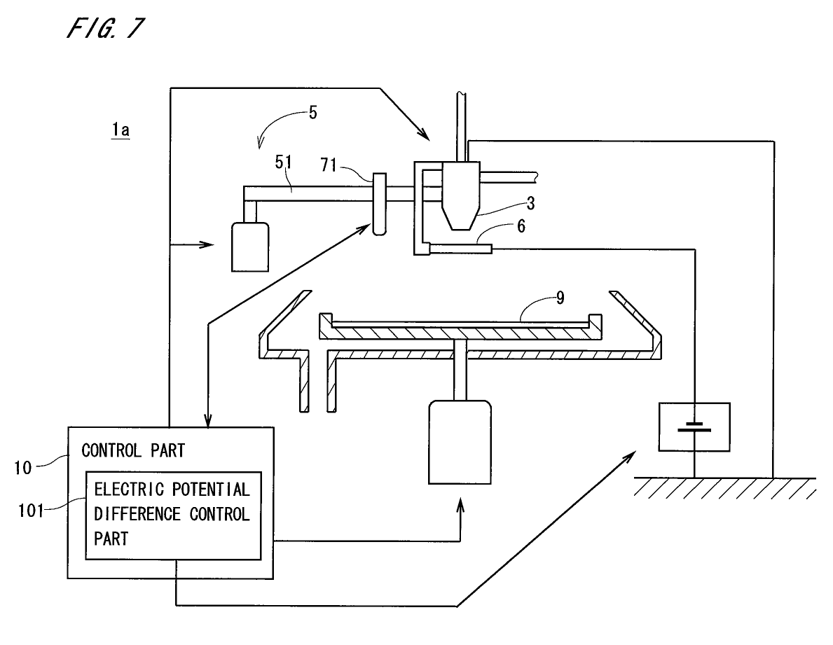

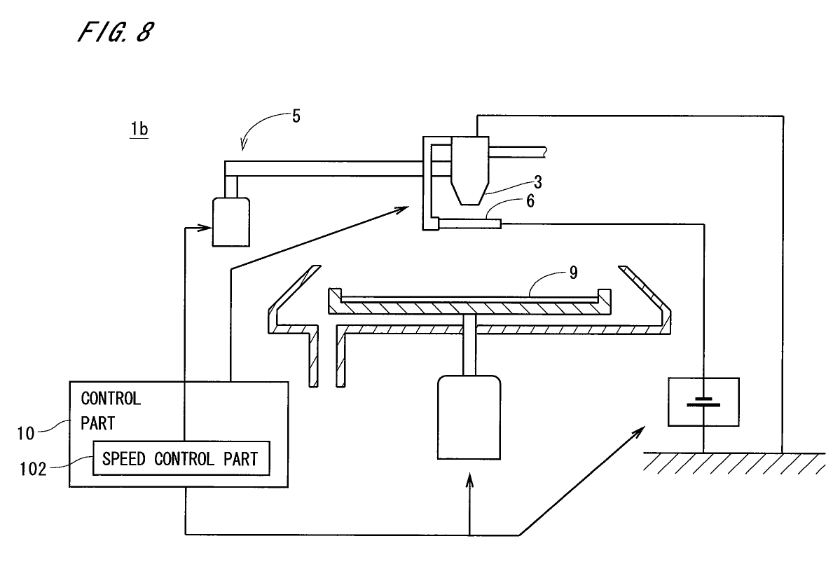

As shown in FIG. 1, the substrate processing apparatus 1 comprises a substrate holding part 2 holding the substrate 9 in contact with a lower main surface of the substrate 9 (hereinafter, the lower main surface is referred to as “lower surface”), an applying part 3 positioned above the substrate 9 for applying the cleaning solution onto an upper main surface of the substrate 9 (hereinafter, the upper main surface is referred to as “upper surface”), a cleaning solution supply part (i.e., processing liquid supply part) 41 which supplies the cleaning solution into the applying part 3 and has a circular section, a gas supply part 42 for supplying carrier gas into the applying part 3 independently from the cleaning solution supply part 41, an induction electrode 6 which is fixed with respect to the applying part 3 with interposing a nonconductive holding member 35 and located close to an outlet 31 of the applying part 3 between the applying part 3 and the substrate 9, an applying part moving mechanism 5 for moving the applying part 3 and the induction electrode 6 in parallel with the upper surface of the substrate 9 relatively to the substrate 9, and a control part 10 for controlling these constituent elements. In FIG. 1, a part of the substrate holding part 2 is shown cross-sectionally for convenience of illustration (same as in FIGS. 7, 8, 10 and 11).

The substrate holding part 2 has a chuck 21 for holding the approximately disk-shaped substrate 9 in contact with the lower surface and the periphery of the substrate 9, a rotation mechanism 22 for rotating the substrate 9 together with the chuck 21, and a process cup 23 covering the circumference of the chuck 21. The rotation mechanism 22 has a shaft 221 coupled to the lower surface of the chuck 21 and a motor 222 for rotating the shaft 221. By driving the motor 222, the substrate 9 rotates together with the shaft 221 and the chuck 21. The process cup 23 has a side wall 231 which is positioned around the circumference of the chuck 21 and prevents the cleaning solution applied onto the substrate 9 from splashing around, and a drain outlet 232 which is provided in the lower part of the process cup 23 and discharges the cleaning solution applied onto the substrate 9.

The applying part moving mechanism 5 comprises an arm 51 whose top end is fixed to the applying part 3 and a motor 52 for oscillating the arm 51. By driving the motor 52, the applying part 3 and the arm 51 reciprocally move in parallel with the upper surface of the substrate 9 in an arc shape close to a straight line in the substrate processing apparatus 1.

FIG. 2 is a longitudinal sectional view showing the vicinity of the applying part 3. The holding member 35 is omitted in FIG. 2 for convenience of illustration. As shown in FIG. 2, the applying part 3 is an internal mixing two-fluid nozzle, in which a cleaning solution tube 32 with a circular section is provided around the central axis 30 of the applying part 3 (the central axis of the outlet 31). The cleaning solution tube 32 is connected to the cleaning solution supply part 41 on the upper part of the applying part 3, and a space inside the cleaning solution tube 32 is a cleaning solution conduit 321 through which the cleaning solution supplied from the cleaning solution supply part 41 flows. A space between an external wall portion 34 of the applying part 3 and the cleaning solution tube 32 is a gas channel 33 through which carrier gas (which is nitrogen (N₂) gas or air for example, and is N₂ gas in the preferred embodiment) supplied from the gas supply part 42 flows, and the cleaning solution conduit 321 is surrounded by the gas channel 33.

In the applying part 3, a top end of the cleaning solution tube 32 is located at an upper position than the outlet 31 (i.e., the upper part in FIG. 2). The cleaning solution ejected from the cleaning solution tube 32 is mixed with the carrier gas in the applying part 3, fine droplets of the cleaning solution are generated and ejected onto the substrate 9 (see FIG. 1) from the outlet 31 together with the carrier gas. An inner diameter of the outlet 31 is about 2 to 3 mm.

The cleaning solution tube 32 of the applying part 3 (i.e., a portion forming the cleaning solution conduit 321 in the applying part 3) and the cleaning solution supply part 41 connected to the cleaning solution tube 32 are made of conductive carbon (preferably, such as amorphous carbon or glassy carbon), conductive resin (for example, conductive PEEK (poly-ether-ether-ketone), or conductive PTFE (poly-tetra-fluoro-ethylene)). In the preferred embodiment, the cleaning solution tube 32 and the cleaning solution supply part 41 are made of glassy conductive carbon. The glassy carbon is hard carbon material with a uniform and dense structure, and it has excellent conductivity, chemical resistance, heat resistance, and the like.

In the substrate processing apparatus 1, the cleaning solution tube 32 and the cleaning solution supply part 41 are one cleaning solution supply tube for applying the cleaning solution onto the substrate 9, and the whole cleaning solution supply tube is a conductive liquid contact part which contacts the cleaning solution. In the substrate processing apparatus 1, a conductive line 82 is connected to a portion close to the top end of the cleaning solution tube 32 and as shown in FIG. 1, the cleaning solution supply part 41 and the cleaning solution tube 32 (see FIG. 2) are grounded through the conductive line 82.

As shown in FIG. 2, the induction electrode 6 is a plate-like member which is a ring shape surrounding the central axis 30 of the outlet 31, and an outer diameter of the induction electrode 6 is about 15 mm and an inner diameter is about 8 mm. The distance between the induction electrode 6 and the outlet 31 with respect to the direction of the central axis 30 is approximately 3 to 4 mm. The induction electrode 6 which is made of conductive carbon (preferably, such as amorphous carbon or glassy carbon) or conductive resin (for example, conductive PEEK or conductive PTFE) and the applying part 3 are electrically insulated from each other.

In the substrate processing apparatus 1 shown in FIG. 1, the induction electrode 6 is electrically connected to a power supply 81 positioned outside the substrate processing apparatus 1 and an electric potential difference is generated between the induction electrode 6 and the conductive liquid contact part (i.e., the cleaning solution supply part 41 and the cleaning solution tube 32 (see FIG. 2)). Then, charge is induced on the cleaning solution in the vicinity of the outlet 31 of the applying part 3 and droplets of the cleaning solution having charge are ejected from the applying part 3.

Next, discussion will be made on a cleaning process of the substrate 9 in the substrate processing apparatus 1. FIG. 3 is a flowchart showing an operation flow for cleaning the substrate 9. In the substrate processing apparatus 1 shown in FIG. 1, first, after the substrate 9 is held by the chuck 21 of the substrate holding part 2, the motor 222 of the rotation mechanism 22 is driven by the control part 10 to start rotation of the substrate 9 (Steps S11, S12).

Subsequently, an electric potential difference is generated between the induction electrode 6 and the cleaning solution tube 32 of the applying part 3 and charge is induced on a portion in the vicinity of the outlet 31 in the applying part 3 (i.e., the portion is the top end of the cleaning solution tube 32) (Step S13). In the preferred embodiment, an electric potential of approximately −1000 V is applied to the induction electrode 6 and positive charge is induced in the vicinity of the outlet 31 in the applying part 3.

Next, the applying part moving mechanism 5 is driven by the control part 10 to start movement (i.e., oscillation) of the applying part 3 and the induction electrode 6 (Step S14). In the substrate processing apparatus 1, in a state where charge is induced in the vicinity of the outlet 31, the cleaning solution and N₂ gas are supplied into the applying part 3, positive charge is induced on the cleaning solution in the vicinity of the outlet 31 and fine droplets of the cleaning solution are generated. And ejection (i.e., application) of the droplets of the cleaning solution, on which the positive charge is induced, onto the upper surface of the substrate 9 is started (Step S15).

While the applying part 3 applies the cleaning solution onto the upper surface of the substrate 9 above the rotated substrate 9, the applying part 3 and the induction electrode 6 repeat reciprocal movement at a constant speed between the center and periphery of the substrate 9 in parallel with the upper surface of the substrate 9, in an arc shape close to a straight line, the droplets of the cleaning solution are ejected over the whole upper surface of the substrate 9, to remove foreign substances such as unwanted particles adhering on the upper surface. In the substrate processing apparatus 1, by colliding the fine droplets of the cleaning solution on the upper surface of the substrate 9 at high speed, unwanted fine particles such as organic matter adhering on the upper surface can be efficiently removed without damaging a fine pattern formed on the upper surface.

In the substrate processing apparatus 1, while the droplets of the cleaning solution are ejected onto the substrate 9, induction of charge in the vicinity of the outlet 31 is parallelly and continuously performed by the induction electrode 6. In parallel with application of the processing liquid from the applying part 3 and relative movement of the applying part 3 to the substrate 9, an output from the power supply 81 is controlled by an electric potential difference control part 101 of the control part 10, an electric potential difference generated between the induction electrode 6 and the conductive liquid contact part (i.e., the cleaning solution supply part 41 and the cleaning solution tube 32) is changed, and charge induced on the droplets of the cleaning solution is changed (Step S16).

FIG. 4 is a view showing a distribution of electric potentials on the upper surface of the substrate 9, in a case where a cleaning process is performed without induction of charge on the cleaning solution. In FIG. 4, an electric potential in the central portion of the substrate 9 where a surface charge (i.e., an absolute value of electric potential) is maximum is about −13 V and the surface charge becomes smaller as it gets close to the periphery of the substrate 9 (i.e., goes away from the central portion of the substrate 9). Since the substrate 9 is hardly charged before cleaning, it is considered that the above discussed electric potential on the substrate 9 is generated through the cleaning process.

FIG. 5 is a view showing a distribution of electric potentials on the upper surface of the substrate 9, in a case where the whole surface of the substrate 9 is cleaned by the cleaning solution on which a constant charge is induced. As discussed above, since the oxide film is formed on the upper surface of the substrate 9 and charging of the periphery of the substrate 9 is less suppressed than that of the central portion, the surface charge of the periphery of the substrate 9 after cleaning is greater than that of the central portion of the substrate 9.

In the substrate processing apparatus 1 in accordance with the preferred embodiment, the electric potential difference generated between the induction electrode 6 and the cleaning solution tube 32 is changed according to movement of the applying part 3 as shown in FIG. 6A. FIG. 6A is a graph showing a relationship between a relative position of the applying part 3 to the substrate 9 and an electric potential difference between the induction electrode 6 and the cleaning solution tube 32. In FIG. 6A, an origin in the horizontal axis represents the center of the outlet 31 in the applying part 3 is located directly above the center of the substrate 9, and “r” in the horizontal axis represents the center of the outlet 31 is located directly above the periphery of the substrate 9 (same as in FIG. 6B).

As shown in FIG. 6A, in the substrate processing apparatus 1, through the control of the electric potential difference by the electric potential difference control part 101 of the control part 10, the electric potential difference between the induction electrode 6 and the cleaning solution tube 32 in application of the cleaning solution onto the periphery of the upper surface of the substrate 9 (i.e., an area outside the central portion) is made larger than that in application of the cleaning solution onto the central portion of the upper surface of the substrate 9. Thus, it is possible to suppress charging in the periphery of the substrate 9 which is less suppressed than the central portion, at the same extent that the central portion is suppressed, and improve uniformity of the distribution of the electric potentials on the substrate 9 during cleaning.

Though the relationship between the position of the applying part 3 and the electric potential difference shown in FIG. 6A is obtained by experiment in the preferred embodiment, there may be a case where, for example, the distributions of the electric potentials shown in FIGS. 4 and 5 are acquired and stored in advance, and the relationship shown in FIG. 6A is automatically obtained on the basis of the above distributions.

In a state where ejection of the droplets of the cleaning solution onto the substrate 9 is continued, movement of the applying part 3 is performed a predetermined number of times and the whole upper surface of the substrate 9 is cleaned a plurality of times. Then, application of the cleaning solution from the applying part 3 and relative movement of the applying part 3 to the substrate 9 are stopped, and generation of the electric potential difference between the induction electrode 6 and the cleaning solution tube 32 (i.e., induction of charge in the vicinity of the outlet 31) is also stopped (Step S17). Rotation of the substrate 9 is continued until the substrate 9 dries, and afterwards rotation of the substrate 9 is stopped (Step S18). The substrate 9 is loaded from the substrate processing apparatus 1 to complete the cleaning process of the substrate 9 (Step S19).

In the substrate processing apparatus 1 in accordance with the preferred embodiment, since the electric potential difference is generated between the induction electrode 6 and the cleaning solution tube 32, it is possible to generate the droplets of the cleaning solution on which positive charge (i.e., the charge having an opposite polarity to that of the electric potential of the substrate after cleaning is performed without generation of the electric potential difference) is induced, and suppress charging of the substrate 9 during and after cleaning (i.e., charging of the substrate 9 through the cleaning process) by cleaning the substrate 9 with the above droplets of the cleaning solution. In the cleaning process of the substrate 9, the electric potential difference between the induction electrode 6 and the cleaning solution tube 32 is controlled and uniformity of the distribution of the electric potentials on the substrate 9 can be improved.

In the substrate processing apparatus 1, the induction of charge on the droplets of the cleaning solution can be easily achieved by locating the induction electrode 6 close to the outlet 31 of the applying part 3 while simplifying the construction of the substrate processing apparatus 1. The two-fluid nozzle is used as the applying part 3 and it is possible to generate the droplets of the cleaning solution easily and minimize a mechanism for generation and ejection of the droplets. Further, since neutral pure water is utilized as the cleaning solution, even if a copper wiring and the like which can deteriorate in contact with an acid solution (for example, a carbon dioxide (CO₂)-dissolved water) and the like are formed on the substrate 9, it is possible to perform the cleaning process on the substrate 9 while suppressing charging of the substrate 9, without deterioration of the wiring and the like.

Although, as discussed above, the electric potential difference between the induction electrode 6 and the cleaning solution tube 32 is continuously changed on the basis of the relative position of the applying part 3 to the substrate 9 as shown in FIG. 6A in the substrate processing apparatus 1, change of the electric potential difference is not necessarily performed as shown in FIG. 6A. For example, the electric potential difference between the induction electrode 6 and the cleaning solution tube 32 may be switched between zero and a predetermined value other than zero by the electric potential difference control part 101 of the control part 10 as shown in FIG. 6B.

In this case, when application of the cleaning solution onto respective areas on the upper surface of the substrate 9 is repeated a plurality of times, in application of the cleaning solution onto the central portion having a larger extent of suppression of charging, the electric potential difference between the induction electrode 6 and the cleaning solution tube 32 is made to zero at e.g., half of the plurality of times of application. In application of the cleaning solution onto the periphery of the substrate 9, the electric potential difference is made to a predetermined value other than zero. Thus, it is possible to suppress charging in the periphery of the substrate 9 which is less suppressed than the central portion, at the same extent that the central portion is suppressed.

As described above, the electric potential difference between the induction electrode 6 and the cleaning solution tube 32 is switched at the two phases and it is possible to improve uniformity of the distribution of the electric potentials on the substrate 9 while simplifying change of the electric potential difference. According to characteristics of charging of the substrate 9, the electric potential difference between the induction electrode 6 and the cleaning solution tube 32 may be switched at three phases, for example, the central portion of the substrate 9, the periphery, and an area between the central portion and the periphery.

Next, discussion will be made on a substrate processing apparatus in accordance with the second preferred embodiment of the present invention. FIG. 7 shows a substrate processing apparatus la in accordance with the second preferred embodiment. As shown in FIG. 7, the substrate processing apparatus la further comprises a surface electrometer 71 for measuring an electric potential on the upper surface of the substrate 9, in addition to the constituent elements of the substrate processing apparatus 1 shown in FIG. 1. The surface electrometer 71 is fixed on the arm 51 of the applying part moving mechanism 5, and the applying part moving mechanism 5 moves the surface electrometer 71 and the applying part 3 relatively to the substrate 9. Other constituent elements are the same as those of FIGS. 1 and 2 and are represented by the same reference signs in the following discussion.

The cleaning process of the substrate 9 in the substrate processing apparatus 1a is almost the same as that in the first preferred embodiment (see FIG. 3), but the method of change of the electric potential difference between the induction electrode 6 and the cleaning solution tube 32 in Step S16 in the substrate processing apparatus 1a is different from that in the first preferred embodiment. In the substrate processing apparatus 1a, concurrently with the relative movement of the applying part 3 to the substrate 9 and application of the cleaning solution in Step S16, the surface electrometer 71 moves in parallel with the upper surface of the substrate 9 and continuously measures an electric potential on the upper surface of the substrate 9 while repeating reciprocal movement between the center and periphery of the substrate 9 in an arc shape close to a straight line, and a distribution of electric potentials on the upper surface of the substrate 9 is measured.

The electric potential difference between the induction electrode 6 and the cleaning solution tube 32 is changed on the basis of an output from the surface electrometer 71 (i.e., the distribution of the electric potentials on the upper surface of the substrate 9), by the electric potential difference control part 101 of the control part 10. Proportional control, PID control, or the like are used for control of the electric potential difference by the electric potential difference control part 101. The above electric potential difference (i.e., the electric potential difference opposite to the measured electric potential) is made larger with increase of the surface charge on the upper surface of the substrate 9 (i.e., increase of the absolute value of the measured electric potential), and the charge induced on the cleaning solution increases to suppress charging of the substrate 9.

As discussed above, since the electric potential difference between the induction electrode 6 and the cleaning solution tube 32 is changed according to the distribution of the electric potentials in the cleaning process of the substrate 9, it is possible to more improve uniformity of the distribution of the electric potentials on the substrate 9 while suppressing charging of the substrate 9. Also, it is possible to prevent the substrate 9 from being charged to a reverse electric potential by excessive induction of charge.

Next, discussion will be made on a substrate processing apparatus in accordance with the third preferred embodiment of the present invention. FIG. 8 shows a substrate processing apparatus 1b in accordance with the third preferred embodiment. As shown in FIG. 8, the substrate processing apparatus 1b comprises a speed control part 102 for changing a relative movement speed of the applying part 3 to the substrate 9, instead of the electric potential difference control part 101 in the substrate processing apparatus 1 shown in FIG. 1. Other constituent elements are the same as those of FIGS. 1 and 2 and are represented by the same reference signs in the following discussion.

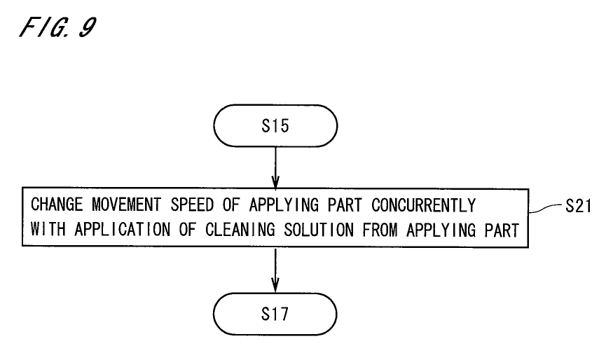

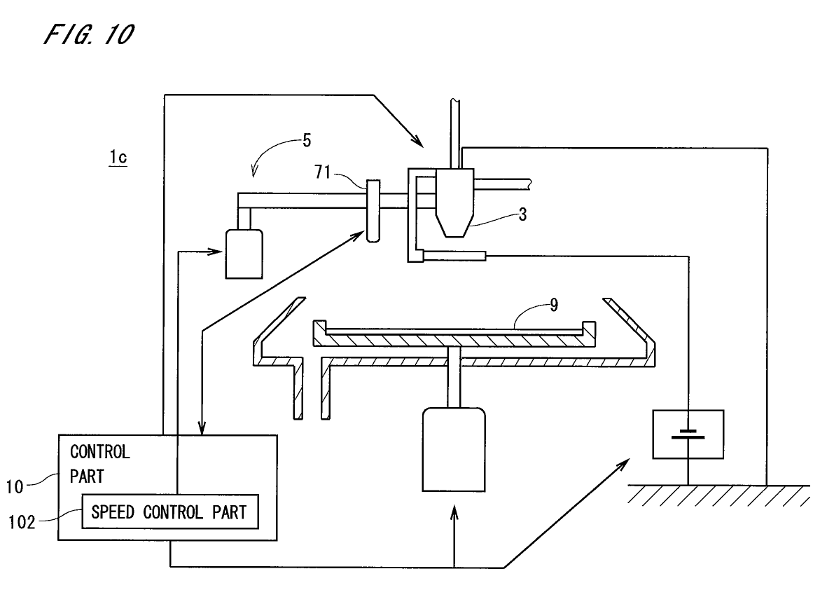

FIG. 9 is a flowchart showing a part of operation flow for cleaning the substrate 9 in the substrate processing apparatus 1b. In the substrate processing apparatus 1b, Step S21 in FIG. 9 is performed instead of Step S16 in FIG. 3, and operations before and after Step S21 are the same as those of Steps S11 to S15 and Steps S17 to S19, respectively.

When cleaning of the substrate 9 is performed in the substrate processing apparatus 1b, Steps S11 to S15 (see FIG. 3) are performed to eject droplets of the cleaning solution on which positive charge is induced onto the upper surface of the substrate 9, similarly to the first preferred embodiment. While the applying part 3 applies the cleaning solution onto the upper surface of the substrate 9 above the rotated substrate 9, the applying part 3 and the induction electrode 6 repeat reciprocal movement, which occurs in a substantial straight line, between the center and periphery of the substrate 9 in parallel with the upper surface of the substrate 9. An electric potential difference generated between the induction electrode 6 and the cleaning solution tube 32 (see FIG. 2) is constant in the substrate processing apparatus 1b.

In the relative movement of the applying part 3 and the induction electrode 6 to the substrate 9 which is concurrently performed with application of the cleaning solution from the applying part 3, the applying part moving mechanism 5 is controlled by the speed control part 102 of the control part 10, and a relative movement speed of the applying part 3 and the induction electrode 6 to the substrate 9 is changed on the basis of the characteristics of charging of the substrate 9 and the relative position of (the outlet 31 of) the applying part 3 to the substrate 9 (Step S21) in the substrate processing apparatus 1b.

As discussed above, a degree (effect) of suppression of charging in the central portion of the substrate 9 where an oxide film is formed on the upper surface is greater than that in the periphery. In the substrate processing apparatus 1b, the relative movement speed of the applying part 3 in application of the cleaning solution onto the periphery of the upper surface of the substrate 9 (i.e., an area outside the central portion) is made smaller than that in application of the cleaning solution onto the central portion of the upper surface of the substrate 9. Thus, an amount per unit area of the droplets of the cleaning solution having charge which are ejected onto the periphery of the substrate 9, where charging is less suppressed than the central portion, is made greater than that of the droplets of the cleaning solution which are ejected onto the central portion of the substrate 9.

Consequently, similarly to the first preferred embodiment, it is possible to suppress charging in the periphery of the substrate 9 at the same extent that the central portion is suppressed, and improve uniformity of the distribution of the electric potentials on the substrate 9 during cleaning while suppressing charging of the substrate 9 through the cleaning process. In the substrate processing apparatus 1b, when cleaning of the whole upper surface of the substrate 9 is finished, Steps S17 to S19 (see FIG. 3) are performed to complete the cleaning process of the substrate 9.

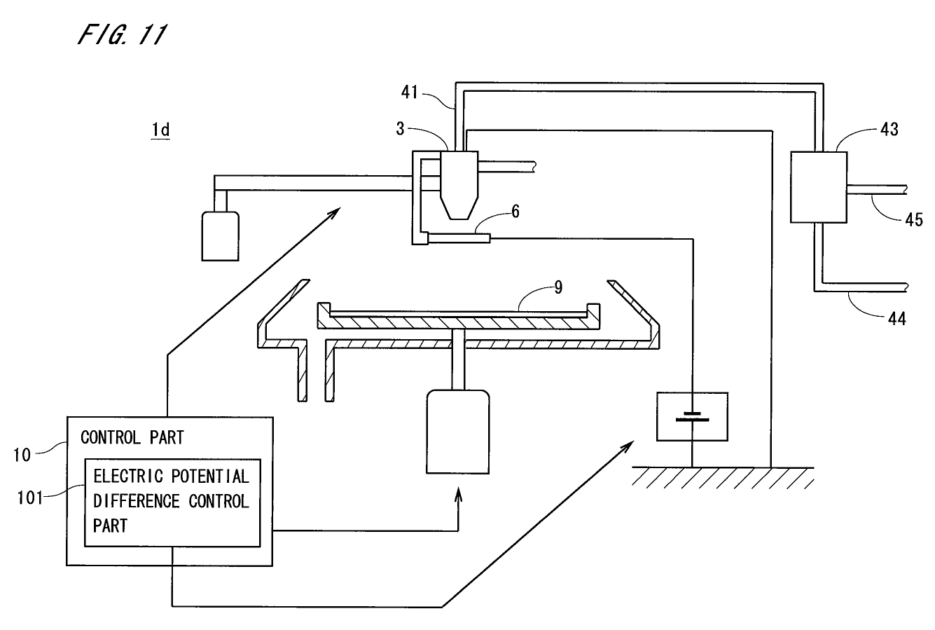

Next, discussion will be made on a substrate processing apparatus in accordance with the forth preferred embodiment of the present invention. FIG. 10 shows a substrate processing apparatus 1c in accordance with the forth preferred embodiment. As shown in FIG. 10, the substrate processing apparatus 1c further comprises a surface electrometer 71 for measuring an electric potential on the upper surface of the substrate 9, in addition to the constituent elements of the substrate processing apparatus 1b shown in FIG. 8. Other constituent elements are the same as those of FIG. 8 and are represented by the same reference signs in the following discussion.

The cleaning process of the substrate 9 in the substrate processing apparatus I c is almost the same as that in the third preferred embodiment (see FIGS. 3 and 9), but the method of change of the movement speed of the applying part 3 in Step S21 in the substrate processing apparatus 1c is different from that in the third preferred embodiment. In the substrate processing apparatus 1c, concurrently with the relative movement of the applying part 3 to the substrate 9 and application of the cleaning solution, the surface electrometer 71 moves in parallel with the upper surface of the substrate 9 and continuously measures an electric potential on the upper surface of the substrate 9 while repeating reciprocal movement, which occurs in a substantial straight line, between the center and periphery of the substrate 9, and a distribution of electric potentials on the upper surface of the substrate 9 is measured.

The applying part moving mechanism 5 is controlled by the speed control part 102 of the control part 10 on the basis of an output from the surface electrometer 71 (i.e., the distribution of the electric potentials on the upper surface of the substrate 9) to change the relative movement speed of the applying part 3 to the substrate 9. Proportional control, PID control, or the like are used for control of the movement speed of the applying part 3 by the speed control part 102, similarly to the control of the electric potential difference in the substrate processing apparatus 1a in accordance with the second preferred embodiment. With increase of the surface charge on the upper surface of the substrate 9, the above movement speed is made smaller and an amount per unit area of the droplets of the cleaning solution having charge which are ejected onto the substrate 9 is made greater, to suppress charging of the substrate 9.

As discussed above, since the movement speed of the applying part 3 is changed according to the distribution of the electric potentials in the cleaning process of the substrate 9, it is possible to more improve uniformity of the distribution of the electric potentials on the substrate 9 while suppressing charging of the substrate 9. Also, it is possible to prevent the substrate 9 from being charged to a reverse electric potential by excessive induction of charge.

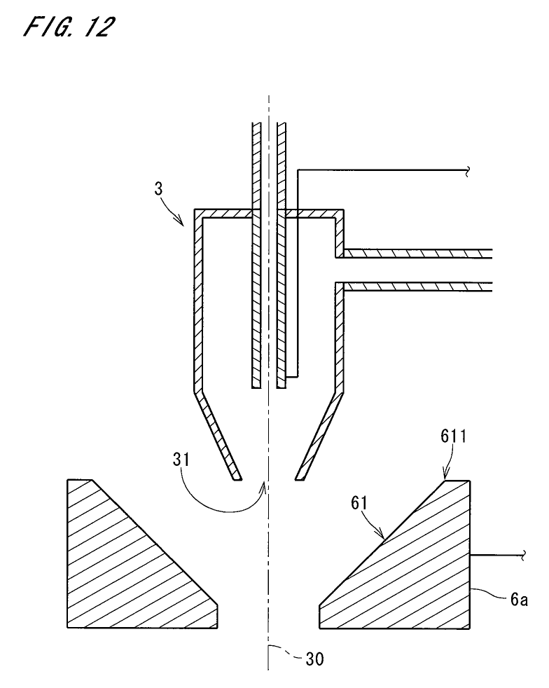

Next, discussion will be made on a substrate processing apparatus in accordance with the fifth preferred embodiment of the present invention. FIG. 11 shows a substrate processing apparatus 1d in accordance with the fifth preferred embodiment. As the cleaning solution, a CO₂-dissolved water where CO₂ is dissolved into pure water is used in the substrate processing apparatus 1d. As shown in FIG. 11, the substrate processing apparatus 1d further comprises a gas-liquid mixer 43 for generating the CO₂-dissolved water, in addition to the constituent elements of the substrate processing apparatus 1 shown in FIG. 1. Other constituent elements are the same as those of FIGS. 1 and 2 and are represented by the same reference signs in the following discussion.

As shown in FIG. 11, in the substrate processing apparatus 1d, the gas-liquid mixer 43 is connected to the cleaning solution supply part 41 which supplies the cleaning solution into the applying part 3. A pure water supply tube 44 and a CO₂ supply tube 45 respectively attached to a pure water supply source and a CO₂ supply source which are not shown are connected to the gas-liquid mixer 43.

A gas-dissolving membrane which is made of a hollow fiber membrane or the like and has gas permeability and liquid impermeability is provided in the gas-liquid mixer 43. An internal space of the gas-liquid mixer 43 is separated into two supply spaces by the gas-dissolving membrane, and pure water and CO₂ are individually supplied into the two supply spaces. Since a pressure of the CO₂ is made higher than that of the pure water, the CO₂ passes through the gas-dissolving membrane and dissolves into the pure water to generate a CO₂-dissolved water. Unwanted gas dissolved into the pure water is degassed by a vacuum pump which is not shown.

In the gas-liquid mixer 43, supply pressures and the like of the CO₂ and the pure water are controlled so that a specific resistance of the CO₂-dissolved water becomes a predetermined value. Preferably, the specific resistance of the CO₂-dissolved water is made to be equal to or greater than 1×10² Ωm and equal to or smaller than 4×10³ Ωm (more preferably, equal to or greater than 5×10² Ωm and equal to or smaller than 4×10³ Ωm), and it is about 1×10³ Ωm in the preferred embodiment.

In the substrate processing apparatus 1d, concurrently with application of the processing liquid from the applying part 3 and the relative movement of the applying part 3 to the substrate 9, the electric potential difference generated between the induction electrode 6 and the cleaning solution tube 32 (see FIG. 2) is changed on the basis of the characteristics of charging of the substrate 9 and the relative position of the applying part 3 to the substrate 9, by the electric potential difference control part 101, similarly to the first preferred embodiment. Thus, it is possible to improve uniformity of the distribution of the electric potentials on the substrate 9 while suppressing charging of the substrate 9.

Since the CO₂-dissolved water whose specific resistance is lower (i.e., conductivity is higher) than the pure water is used as the cleaning solution in the substrate processing apparatus 1d, it is possible to more suppress charging of the upper surface of the substrate 9, which occurs in collision between the droplets of the cleaning solution and the substrate 9.

Though the preferred embodiments of the present invention have been discussed above, the present invention is not limited to the above-discussed preferred embodiments, but allows various variations.

Though, in the above preferred embodiments, discussions have been made on the case where the degree of suppression of charging in the central portion of the substrate 9 is greater than that in the periphery, in a case where for example a degree of suppression of charging in the whole area on the substrate 9 is equal, the electric potential difference between the induction electrode 6 and the cleaning solution tube 32 in application of the cleaning solution onto the central portion of the substrate 9 is made larger than that in application of the cleaning solution onto the periphery of the substrate 9 in the substrate processing apparatus 1 in accordance with the first preferred embodiment. Thus, it is possible to greatly suppress charging in the central portion of the substrate 9 having a larger surface charge than the periphery in a distribution of electric potentials when charge is not induced, in comparison with the periphery, and improve uniformity of the distribution of electric potentials on the substrate 9.

Similarly to the substrate processing apparatus 1b in accordance with the third preferred embodiment, in a case where a degree of suppression of charging in the whole area on the substrate 9 is equal, the movement speed of the applying part 3 in application of the cleaning solution onto the central portion of the substrate 9 is made smaller than that in application of the cleaning solution onto the periphery of the substrate 9. It is possible to improve uniformity of the distribution of electric potentials on the substrate 9.

In the substrate processing apparatus 1d in accordance with the fifth preferred embodiment, there may be a case where the surface electrometer 71 for measuring the distribution of electric potentials on the upper surface of the substrate 9 during cleaning of the substrate 9 is provided to change the electric potential difference generated between the induction electrode 6 and the cleaning solution tube 32 (see FIG. 2) on the basis of the output from surface electrometer 71, like in the substrate processing apparatus 1a in accordance with the second preferred embodiment.

In the substrate processing apparatus 1d, by control of the movement speed of the applying part 3 in relative movement of the applying part 3 to the substrate 9 which is concurrently performed with application of the cleaning solution from the applying part 3, uniformity of the distribution of electric potentials on the substrate 9 may be improved while suppressing charging of the substrate 9. In this case, the speed control part 102 (see FIG. 8) for controlling the applying part moving mechanism 5 is provided instead of the electric potential difference control part 101.

Concurrently with application of the cleaning solution from the applying part 3 and relative movement of the applying part 3 to the substrate 9, both of the controls of the electric potential difference generated between the induction electrode 6 and the cleaning solution tube 32 and the movement speed of the applying part 3 may be performed to improve uniformity of the distribution of electric potentials on the substrate 9 while suppressing charging of the substrate 9 in the substrate processing apparatuses in accordance with the above preferred embodiments.

The relative movement of the applying part 3 to the substrate 9 may be a reciprocal movement in an arc shape close to a straight line, which is performed through one point on the periphery of the substrate 9 and the center of the substrate 9 and other point on the periphery which is approximately opposite to the one point across the center of the substrate 9. The relative movement of the applying part 3 to the substrate 9 can be also performed by moving the substrate 9 and the substrate holding part 2 in horizontal direction.

In the substrate processing apparatus, the distance between the induction electrode 6 and the outlet 31 of the applying part 3 with respect to the direction of the central axis 30 may be different from the distance described in the above preferred embodiments, as long as it is the distance where induction of charge in the vicinity of the outlet 31 can be performed with an actual power supply. The induction electrode 6 can be located at the position of the outlet 31 (i.e., around the outlet 31) of the applying part 3 with respect to the direction of the central axis 30.

The shape of the induction electrode is not necessarily limited to a ring shape which is platy in the substrate processing apparatus. FIG. 12 is a longitudinal sectional view showing the vicinity of the applying part 3 in the substrate processing apparatus comprising other induction electrode 6a. The induction electrode 6a is a ring shape about the central axis 30 of the outlet 31 in the applying part 3, and an internal surface of the induction electrode 6a (i.e., the surface facing the central axis 30) is an inclined surface 61 which is located around the outlet 31 and inclined to the central axis 30 of the outlet 31. The inclined surface 61 is a part of conical surface having the apex on the central axis 30 of the outlet 31, and the apex is located on the side of the substrate 9 (see FIG. 1). The angle formed between a generatrix of the conical surface and the central axis 30 is made to 45 degrees. A position of an outer edge 611 of the inclined surface 61 with respect to the direction of the central axis 30 coincides with that of the outlet 31 with respect to the direction of the central axis 30.

By forming the induction electrode 6a as discussed above, the distance between the central axis 30 and the inclined surface 61 with respect to the direction perpendicular to the central axis 30 is longer as it gets close to the outlet 31 between the applying part 3 and the upper surface of the substrate 9, in any cross section of the inclined surface 61 of the induction electrode 6a which is cut by a plane including the central axis 30. Since an area of the induction electrode 6a is made greater in a position close to the outlet 31, charge can be efficiently induced on the cleaning solution. The inclined surface 61 is a part of conical surface and it is possible to easily form the inclined surface 61 by cutting or the like.

The inclined surface 61 of the induction electrode 6a may be a part of spherical surface around the center of the outlet 31, i.e., a surface of revolution around the central axis 30 which is a ring shape surrounding the central axis 30 of the outlet 31 (in other words, an enveloping surface which is formed by rotating an object around the central axis 30). Similarly to the above case, the distance between the central axis 30 and the inclined surface 61 with respect to the direction perpendicular to the central axis 30 is longer as it gets close to the outlet 31 between the applying part 3 and the upper surface of the substrate 9, in any cross section of the inclined surface 61 which is cut by a plane including the central axis 30, and charge can be efficiently induced on the cleaning solution.

The shape of the inclined surface 61 where the distance between the central axis 30 and the inclined surface 61 is longer as it gets close to the outlet 31 can be a surface of revolution which is formed by rotating an arc with the central angle of 90 degrees away from the central axis 30. Each of the inside and outside edges of the inclined surface 61 may be an approximate rectangle (specifically, a square where each of four corners is rounded in an arc shape) in the plan view. In this case, each of four planes making the inclined surface 61 has inside and outside edges each of which is a straight side of the above approximate rectangle, and the four planes form a cylindrical surface. Each surface of four corners is sandwiched by two of the four planes and the each surface is a part of spherical surface.

Furthermore, the inclined surface 61 may be a partial surface of square pyramid having the apex on the central axis 30 of the outlet, and the apex is located on the side of the substrate. The inclined surface 61 can be a partial surface of polygonal pyramid having the apex on the central axis of the outlet, other than a square pyramid. Also, the inclined surface 61 may be a convex surface toward the outlet, and the outer surface of the inclined surface 61 may be an inclined surface which is inclined to the central axis 30.

The liquid contact part of the applying part 3, between which and the induction electrode 6 the electric potential difference is generated, is not necessarily provided in the cleaning solution tube 32, and the cleaning solution supply part 41 may be grounded through the conductive line 82, for example. Generation of the electric potential difference between the induction electrode 6 and the liquid contact part which is on the side of the applying part 3 may be performed by grounding the induction electrode 6 and connecting the liquid contact part to the power supply 81 or by connecting both electrodes of the power supply 81 to the induction electrode 6 and the liquid contact part, respectively. However, from the viewpoint of simplification of the construction of the substrate processing apparatus, it is preferable that the liquid contact part is grounded and the induction electrode 6 is connected to the power supply 81, like in the above preferred embodiments.

The applying part 3 is not necessarily limited to the internal mixing two-fluid nozzle but may be an external mixing two-fluid nozzle, for example, which generates droplets of the cleaning solution by individually ejecting the cleaning solution and carrier gas outside the applying part 3 and mixing them in the vicinity outside the outlet 31. In the substrate processing apparatus, there may be a case where droplets of cleaning solution generated in another apparatus are supplied into the applying part 3 and the droplets are ejected from the applying part 3 together with carrier gas or only the cleaning solution is supplied into the applying part 3 and ejected as the droplets.

Droplets of the cleaning solution are not necessarily applied from the applying part 3 in the substrate processing apparatus. For example, a pillar of cleaning solution can be applied to perform cleaning of the substrate 9 or cleaning solution in which ultrasonic wave is generated may be applied to perform cleaning of the substrate 9. As discussed above, since the substrate processing apparatus can suppress charging caused by cleaning of the substrate 9, it is more suitable for cleaning by the droplets where a surface charge of the substrate 9 becomes larger than cleaning by the pillar of cleaning solution.

In the substrate processing apparatuses in accordance with the above preferred embodiments, a polarity of electric potential and a surface charge of the substrate which are created in cleaning are different depending on a kind of substrate (for example, a kind of insulating film or a kind of wiring metal which are formed on an upper surface of a semiconductor substrate and both kinds of insulating film and wiring metal), and therefore, the electric potential difference generated between the induction electrode 6 and the applying part 3 in the substrate processing apparatus is changed according to kinds of substrate. For example, in a case where a resist film is formed on a substrate, the upper surface of the substrate is positively charged by cleaning and a positive voltage is applied to the induction electrode 6 to induce negative charge on the cleaning solution.

In the substrate processing apparatuses in accordance with the first to fourth preferred embodiments, liquid other than pure water can be utilized as cleaning solution and for example, a ZEORORA (trademark) of ZEON Corporation, a Novec (trademark) HFE (specific resistance: 3.3×10⁷ Ωm) of 3M Company, or the like, which are fluorine-based cleaning solutions and have a relatively high specific resistance, can be used as cleaning solution. Instead of the CO2-dissolved water used in the substrate processing apparatus 1d in accordance with the fifth preferred embodiment, an aqueous solution where rare gas such as xenon (Xe), methane, or the like is dissolved into pure water or an aqueous solution where a chemical solution such as hydrochloric acid (HCl), ammonia solution (NH₃), hydrogen peroxide solution (H₂O₂) is slightly mixed into pure water can be utilized as cleaning solution with a lower specific resistance than pure water. In the case of dissolving the chemical solution such as HCl or NH₃ into pure water, a mixing valve or the like is used in place of the gas-liquid mixer 43. As discussed above, since the substrate processing apparatuses in accordance with the preferred embodiments can suppress charging caused by cleaning of the substrate 9, they are especially suitable for cleaning with cleaning solution having a high specific resistance (i.e., cleaning solution having a specific resistance of 1×10² Ωm or more) where a surface charge of the substrate 9 becomes larger than cleaning with cleaning solution having a low specific resistance.

The substrate processing apparatuses in accordance with the above preferred embodiments may be utilized in various stages other than cleaning of a substrate, and may be utilized, for example, in a rinsing process of a substrate cleaned with a chemical solution. In this case, a rinse agent such as pure water is used as processing liquid supplied onto a substrate. Also, the substrate processing apparatus may be used for processing various substrates such as a printed circuit board or a glass substrate for a flat panel display, as well as a semiconductor substrate.

While the invention has been shown and described in detail, the foregoing description is in all aspects illustrative and not restrictive. It is therefore understood that numerous modifications and variations can be devised without departing from the scope of the invention.

This application claims priority benefit under 35 U.S.C. Section 119 of Japanese Patent Application No. 2006-144431 filed in the Japan Patent Office on May 24, 2006, the entire disclosure of which is incorporated herein by reference.

What is claimed is:

1. A substrate processing apparatus for processing a substrate by applying processing liquid onto said substrate, comprising:
an applying part for applying processing liquid from an outlet onto a main surface of a substrate;
a processing liquid supply part for supplying said processing liquid into said applying part;
an induction electrode which is electrically insulated from said applying part and located close to said outlet of said applying part or located at a position of said outlet, said induction electrode inducing charge on said processing liquid in the vicinity of said outlet by generating an electric potential difference between said induction electrode and a liquid contact part which is conductive and contacts said processing liquid in said applying part or said processing liquid supply part;
an applying part moving mechanism for moving said applying part in parallel with said main surface of said substrate relatively to said substrate; and
an electric potential difference control part for changing an electric potential difference generated between said liquid contact part and said induction electrode, concurrently with relative movement of said applying part to said substrate and application of said processing liquid.

2. The substrate processing apparatus according to claim 1, wherein
said electric potential difference between said liquid contact part and said induction electrode is switched between zero and a predetermined value other than zero by said electric potential difference control part.

3. The substrate processing apparatus according to claim 1, further comprising:
a surface electrometer for measuring a distribution of electric potentials on said main surface of said substrate concurrently with relative movement of said applying part to said substrate and application of said processing liquid, and
said electric potential difference control part changes said electric potential difference between said liquid contact part and said induction electrode on the basis of an output from said surface electrometer.

4. The substrate processing apparatus according to claim 1, wherein
an electric potential difference between said liquid contact part and said induction electrode in application of said processing liquid onto an area outside a central portion of said main surface of said substrate is made larger than that in application of said processing liquid onto said central portion of said main surface.

5. The substrate processing apparatus according to claim 1, wherein
said applying part ejects droplets of said processing liquid onto said substrate.

6. The substrate processing apparatus according to claim 5, wherein
said applying part generates said droplets of said processing liquid by mixing said processing liquid and carrier gas in said applying part or in the vicinity outside said outlet.

7. The substrate processing apparatus according to claim 1, wherein
a specific resistance of said processing liquid is equal to or greater than 1×10² Ωm.

8. The substrate processing apparatus according to claim 7, wherein
said processing liquid is pure water.

9. The substrate processing apparatus according to claim 7, wherein
said processing liquid is a CO₂-dissolved water where CO₂ gas is dissolved into pure water.

10. A substrate processing apparatus for processing a substrate by applying processing liquid onto said substrate, comprising:
an applying part for applying processing liquid from an outlet onto a main surface of a substrate;
a processing liquid supply part for supplying said processing liquid into said applying part;
an induction electrode which is electrically insulated from said applying part and located close to said outlet of said applying part or located at a position of said outlet, said induction electrode inducing charge on said processing liquid in the vicinity of said outlet by generating an electric potential difference between said induction electrode and a liquid contact part which is conductive and contacts said processing liquid in said applying part or said processing liquid supply part;
an applying part moving mechanism for moving said applying part in parallel with said main surface of said substrate relatively to said substrate; and
a speed control part for changing a relative movement speed of said applying part to said substrate by control of said applying part moving mechanism, in relative movement of said applying part to said substrate which is concurrently performed with application of said processing liquid from said applying part.

11. The substrate processing apparatus according to claim 10, further comprising:
a surface electrometer for measuring a distribution of electric potentials on said main surface of said substrate concurrently with relative movement of said applying part to said substrate and application of said processing liquid, and
said speed control part changes said relative movement speed of said applying part on the basis of an output from said surface electrometer.

12. The substrate processing apparatus according to claim 10, wherein
said relative movement speed of said applying part in application of said processing liquid onto an area outside a central portion of said main surface of said substrate is made smaller than that in application of said processing liquid onto said central portion of said main surface.

13. The substrate processing apparatus according to claim 10, wherein
said applying part ejects droplets of said processing liquid onto said substrate.

14. The substrate processing apparatus according to claim 13, wherein
said applying part generates said droplets of said processing liquid by mixing said processing liquid and carrier gas in said applying part or in the vicinity outside said outlet.

15. The substrate processing apparatus according to claim 10, wherein
a specific resistance of said processing liquid is equal to or greater than 1×10² Ωm.

16. The substrate processing apparatus according to claim 15, wherein
said processing liquid is pure water.

17. The substrate processing apparatus according to claim 15, wherein
said processing liquid is a CO₂-dissolved water where CO₂ gas is dissolved into pure water.

18. A substrate processing method of processing a substrate by applying processing liquid onto said substrate, comprising the steps of:
a) applying processing liquid onto a main surface of a substrate from an applying part connected to a processing liquid supply part and moving said applying part in parallel with said main surface of said substrate relatively to said substrate;
b) inducing charge on said processing liquid in the vicinity of an outlet of said applying part concurrently with said step a), by generating an electric potential difference between an induction electrode which is electrically insulated from said applying part and located close to said outlet or located at a position of said outlet and a liquid contact part which is conductive and contacts said processing liquid in said applying part or said processing liquid supply part; and
c) changing an electric potential difference generated between said liquid contact part and said induction electrode concurrently with said steps a) and b).

19. A substrate processing method of processing a substrate by applying processing liquid onto said substrate, comprising the steps of:
a) applying processing liquid onto a main surface of a substrate from an applying part connected to a processing liquid supply part and moving said applying part in parallel with said main surface of said substrate relatively to said substrate;
b) inducing charge on said processing liquid in the vicinity of an outlet of said applying part concurrently with said step a), by generating an electric potential difference between an induction electrode which is electrically insulated from said applying part and located close to said outlet or located at a position of said outlet and a liquid contact part which is conductive and contacts said processing liquid in said applying part or said processing liquid supply part; and
c) changing a relative movement speed of said applying part to said substrate concurrently with said steps a) and b).
